(19) United States
(12) Patent Application Publication
(10) Pub. No.: US 2026/0247952 A1
(43) Pub. Date: Aug. 20, 2026

(54) SEMICONDUCTOR PACKAGE WITH EMBEDDED INTERCONNECTS

(71) Applicant: TEXAS INSTRUMENTS INCORPORATED, DALLAS, TX (US)

(72) Inventor: ENIS TUNCER, DALLAS, TX (US)

(21) Appl. No.: 19/054,194

(22) Filed: Feb. 14, 2025

(51) Int. Cl. H01L 23/528; H01L 21/768; H01L 23/532

(52) U.S. Cl. CPC H10W 20/435; H10W 20/057; H10W 20/4403

(57) ABSTRACT

A semiconductor device can include a substrate. The substrate can include first and second trench regions that extend through a body of the substrate. The first trench regions include a dielectric material and the second trench regions include a metal material. The second trenched regions with the metal material corresponding to input-output (I/O) interconnects of the semiconductor device (or package).

### TECHNICAL FIELD

This disclosure relates to semiconductor packaging. More particularly, this disclosure relates to a semiconductor package with embedded interconnects.

### BACKGROUND

A semiconductor device is an electronic component made from semiconductor material with controlled electrical conductivity. The term “semiconductor device” can refer to various types of electronics, including individual components, such as diodes, transistors, photonic devices, and power devices, as well as integrated circuits (ICs). An IC can incorporate multiple electronic components and/or circuits into a single chip. A chip, also known as a microchip, silicon chip, or die, is a piece of semiconductor material, usually silicon, on which the IC is fabricated. ICs are built on a wafer and once complete, the wafer is cut to provide individual dies. The die can be mounted on a package substrate or a lead frame and encapsulated in a molding to form an IC package or semiconductor package (device). The IC package is designed to be mounted on a printed circuit board (PCB) and connected to other components in an electronic system.

### SUMMARY

A first example relates to a semiconductor package that includes a substrate. The substrate can include first and second trench regions that extend through a body of the substrate. The first trench regions include a dielectric material and the second trench regions include a metal material. The second trenched regions with the metal material can correspond to input-output (I/O) interconnects of the semiconductor package.

A second example relates to a semiconductor package that includes a substrate. The substrate can include first trench regions and second trench regions. The first and second trench regions extending through a body of the substrate. The first trench regions can be filled with a dielectric material and the second trench regions can be partially filled with a metal material. The second trench regions with the partially filled metal material can correspond to input-output (I/O) interconnects of the semiconductor package.

A third example relates to a method for fabricating a semiconductor package. The method can include forming first trenched regions in a wafer substrate, filling the first trenched regions with a dielectric material, forming second trench regions in the wafer substrate, depositing a conductive material within the second trenched regions and partitioning the wafer substrate into one or more semiconductor packages. The second trench regions with the deposited conductive material can correspond to input-output (I/O) interconnects of the one or more semiconductor packages.

### BRIEF DESCRIPTION OF THE DRAWINGS

FIG. 1A illustrates a diagram of an example of a semiconductor package.

FIG. 1B illustrates a diagram of another example of a semiconductor package.

FIGS. 2-21 illustrates stages of a method(s) for forming a semiconductor device(s).

FIG. 22 illustrates a flowchart of an example method for forming one or more semiconductor devices according to one or more examples herein.

### DETAILED DESCRIPTION

This description relates to a method for fabricating a semiconductor package (device) using a wafer direct packaging process, as described herein. In this process, a semiconductor device can be fabricated at a wafer processing stage (e.g., entirely during the wafer processing stage), eliminating a need for encapsulation and assembly steps as used in existing assembly-based semiconductor packaging techniques. Assembly-based semiconductor packaging techniques require use of separate assembly stages after wafer processing, such as die attachment, encapsulation, wire bonding, flip-chip bumping, and/or lead frame attachment. These techniques rely on assembly materials like mold compounds, solder balls, and die attach adhesives, as well as surface-level bond pads for interconnects, which serve as connection points for solder balls or wires for establishing input-output (I/O) pathways.

By contrast, the wafer direct packaging process integrates I/O interconnects directly into the wafer substrate, bypassing a need for assembly stages and eliminating the need for surface-level bond pads or additional packaging layers and components. Instead, the I/O interconnects embedded within the substrate allow the entire chip to function as the final packaged product (the semiconductor package). This integration simplifies the packaging process, reduces material usage, and avoids common reliability concerns associated with assembly-based methods, such as delamination, thermal expansion mismatches, and mechanical failure. Furthermore, by removing reliance on assembly materials like mold compounds, die attach adhesives, and solder balls, the wafer direct packaging process enables the production of semiconductor packages with improved thermal and mechanical performance. These advantages make the wafer direct packaging process suitable for high-performance and miniaturized semiconductor applications.

Wafer-level packaging (WLP) techniques combined with flip-chip assembly involve a multi-step process for semiconductor packaging. In WLP, interconnects are formed on the wafer, which is then encapsulated with a protective material and diced into individual chips (dies). Following WLP processing, flip-chip assembly is used to attach the individual chips to a mounting substrate, such as a printed circuit board (PCB). During flip-chip assembly, solder balls are placed on bond pads (I/O connections) of each chip, providing both electrical and mechanical connections to the PCB. However, WLP is constrained by a size and pitch of solder balls, which limits a miniaturization and design flexibility of semiconductor packages. In contrast, the wafer direct packaging process, as described herein, provides an alternative method for semiconductor device fabrication. This process employs trenching and metallization techniques to form I/O interconnects directly within the body of a wafer substrate. Unlike WLP, the semiconductor devices fabricated using the wafer direct packaging process do not suffer from size constraints related to solder balls and do not require flip-chip assembly.

According to one or more examples herein, a method is disclosed for fabricating a semiconductor package based on the wafer direct packaging process. In this process, a multi-metal routing layer is formed on a first surface of a wafer substrate. Deep trenches are then etched into the wafer substrate, extending to the multi-metal routing layer, and the trenches can be metalized to create conductive pathways. Once the wafer substrate is diced into individual semiconductor packages, the metalized trenches function as I/O interconnects, establishing electrical connections between the internal circuitry of the semiconductor package and an external system or device, such as a PCB. The wafer direct packaging process eliminates a need for surface-level bond pads and solder balls, as the metalized trenches provide direct pathways for signal, power, and ground routing. This results in a bond pad-less package with high-density interconnects, improved design flexibility, and simplified fabrication. By removing traditional assembly materials and processes, the wafer direct packaging process reduces manufacturing costs and enhances the thermal and mechanical performance of semiconductor devices, making it particularly suitable for high-performance and miniaturized applications.

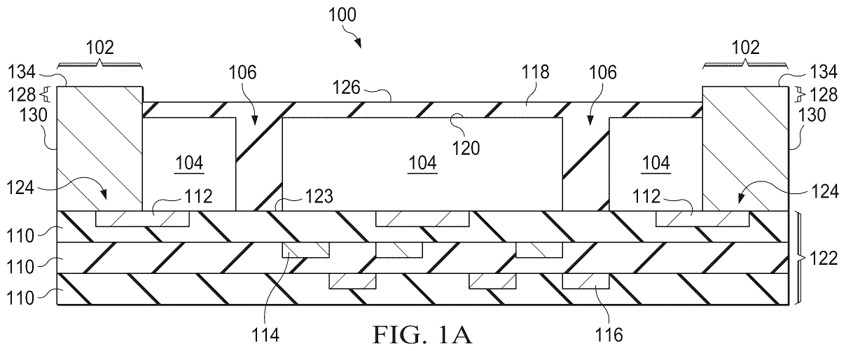

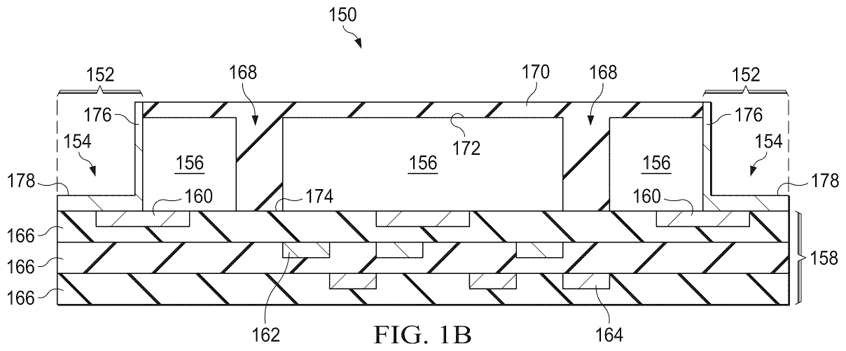

FIG. 1A illustrates a diagram of an example of a semiconductor device 100 with I/O interconnects 102. The example of FIG. 1A is a cross-sectional view of the semiconductor device 100. The I/O interconnects 102 are conductive pathways of the semiconductor device 100 that are used as I/O connections. In some instances, the I/O interconnects 102 can be referred to as embedded interconnects as these interconnects can be embedded within the substrate 104. Because the I/O interconnects 102 are embedded within the substrate 104 and allow for electrical coupling of the semiconductor device 100 with an external system or device (e.g., a PCB), without needing bond pads as in existing semiconductor devices, the semiconductor device 100 can be referred to as a bond pad-less semiconductor device. The I/O interconnects 102 can extend through a body of the substrate 104 and can have body surfaces that are exposed, such as a top surface 134 and a side surface 130. Bonding surfaces of the semiconductor device 100, such as the top and side surfaces 130, 134 of the I/O interconnects 102, can resemble a height and/or geometry of an existing lead frame or substrate packaging, depending on a thickness of a die. For instance, in thick die processes, the top and side surfaces 130, 134 can exhibit greater resemblance to existing lead frame designs, while in thin die processes, the top and side surfaces 130, 134 can align more closely with the geometries typical of substrate packaging.

Unlike free-standing solutions that rely on discrete components and assembly stages, the bonding surfaces, such as the top and side surfaces 130, 134 of the I/O interconnects 102, can be an intrinsic part of the substrate 104. Thus, the physical characteristics of the bonding surfaces on the semiconductor device 100 can be different when compared to semiconductor packages produced according to existing methods, such as described herein. The I/O interconnects 102 and respective bonding surfaces can exhibit a geometry tailored to the structure of the substrate 104, allowing for precise alignment and coupling to external systems, such as PCBs. By integrating the I/O interconnects 102 into the substrate 104, a wafer direct packaging process used for fabricating the semiconductor device 100 is a streamlined solution that reduces material usage, simplifies manufacturing, and enhances the thermal and mechanical reliability of the semiconductor device 100. This bond pad-less configuration makes the process suitable for high-performance and miniaturized applications while eliminating a need for free-standing packaging components.

In some examples, as shown in FIG. 1A, the I/O interconnects 102 can have body portions that extends through the body of the substrate 104 and protruding portions 128 that extend (or protrude) beyond a substrate surface. Each protruding portion 128 of the I/O interconnects 102 can be used for establishing an electrical connection (e.g., using solder) with an external system or device, such as a PCB. Thus, a portion of the I/O interconnects 102 (the protruding portions 128) can extend beyond the substrate surface to allow for electrical and mechanical coupling of the semiconductor device 100 to the external system or device. Because the I/O interconnects 102 function as I/O connection points of the semiconductor device 100 these interconnects can be referred to as external interconnects in some examples.

In some examples, the semiconductor device 100 includes a multi-metal routing layer 122 (for simplicity referred to herein as a routing layer 122), which can be located on a first face of the semiconductor device 100, opposite of a second face of the semiconductor device 100 from which the I/O interconnects 102 protrude. The routing layer 122 includes metal layers 112-116, with metal regions that can be separated from each other by a dielectric material 110, as illustrated in FIG. 1A. The dielectric material 110 used in the routing layer 122 can be made of material, such as silicon dioxide (SiO₂), silicon nitride (Si₃N₄), or low-k dielectric polymers (e.g., carbon-doped oxides). The metal layers 112-116 can function as routing paths for electrical signals, power, and/or ground connections between one or more active regions of the substrate 104 and/or one or more external systems and/or devices (e.g., the PCB). The dielectric material 110 provides electrical insulation between adjacent metal layers in the routing layer 122 to prevent electrical interference and shorting while providing mechanical stability. In the example of FIG. 1A, one or more metal regions of the metal layer 112 can be in physical and electrical contact with a respective interconnect of the I/O interconnects 102, thus establishing a conductive pathway between a respective I/O interconnect of the I/O interconnects 102 and corresponding internal circuitry of the semiconductor device 100.

In some examples, the substrate 104 includes trench regions 106 and trench regions 124, as illustrated in FIG. 1A. The trench regions 106 extend vertically through the substrate 104 and are filled with (or include) a dielectric material 118. The dielectric material 118 can be an insulating material, such as silicon dioxide (SiO₂), silicon nitride (Si₃N₄), spin-on glass (SOG), or parylene, optimized for electrical isolation and mechanical stability within the substrate. The dielectric material 118 provides electrical isolation and mechanical stability within the substrate 104. The dielectric material 118 extends to cover a top surface 120 of the substrate 104, as illustrated in FIG. 1A. Within the trench regions 106, the dielectric material 118 covers portions of the surface 123 of the routing layer 122. Thus, the dielectric material 118 extends from the top surface 120 of the substrate 104, through the body of the trench regions 106, to the surface 123 of the routing layer 122. This arrangement can isolate the I/O interconnects 102 from active regions of the semiconductor device 100 and, in some instances, prevents electrical interference or shorting between the I/O interconnects 102.

As illustrated in FIG. 1A, the trench regions 124 contain a metal material. The trench regions 124 can be filled (e.g., completely or about completely filled) with the metal material. The trench regions 124 with the filled metal material correspond to the I/O interconnects 102 of the semiconductor package 100. The trench regions 124 include a metal material that fills the trench regions 124. The metal material in the trench regions 124 can include a conductive material, such as Copper or Aluminum. In some examples, the I/O interconnects 102 (the metal material) extend vertically within the trench regions 124 and protrude beyond the first face of the semiconductor device 100. The metal material in the trench regions 124 covers different portions of the surface 123 of the routing layer 122 than the dielectric material 118, as illustrated in FIG. 1A. Additionally, the metal material covers at least a portion of a surface of a respective metal region of the metal layer 112 and thus is in physical and electrical contact with an underlying first metal region, thereby providing (or forming) an electrical path to the internal circuitry of the semiconductor device 100.

In some examples, a top portion of the I/O interconnects 102 extends (or projects) beyond the top surface 126 of the dielectric material 118 corresponding to the protruding portion 128, such that the top surface 134 is not aligned with (or flush with) the top surface 126 of the dielectric material 118. The top portion of the I/O interconnects 102 that protrudes from the first face of the substrate 104 functions as a protruding structure for electrical coupling of the semiconductor device 100 with an external system or device. In some examples, the top surface 134 of the I/O interconnects 102 can be substantially flush or coplanar with the top surface 126 of the dielectric material 118, depending on design requirements or manufacturing processes. Thus, in some examples, the top surface 126 of the dielectric material 118 is flush with the top surface 134 of the I/O interconnects 102.

FIG. 1B illustrates a diagram of another example of a semiconductor device 150 formed with I/O interconnects 152. The example of FIG. 1B is a cross-sectional view of the semiconductor device 150. The I/O interconnects 152 are conductive pathways formed within a substrate 156 of the semiconductor device 150 that can be used as I/O connections. In some instances, the I/O interconnects 152 can be referred to as embedded interconnects, as at least a portion of these interconnects is located within the substrate 156. Because the I/O interconnects 152 can be embedded within the substrate 156 and allow for electrical and mechanical coupling of the semiconductor device 150 with an external system or device (e.g., a PCB), without needing bond pads for external connections as in existing semiconductor devices, the semiconductor device 150 can be referred to as a bond pad-less semiconductor device.

In the example of FIG. 1B, the I/O interconnects 152 can be implemented as continuous conductive layer(s) located on inner surfaces of trench regions 154 of the substrate 156 and can be referred to as a trench conductive layer. The conductive layer is a metal material that partially fills the trench regions 154. The trench regions with the partially filled metal material correspond to the I/O interconnects 152 of the semiconductor package 150. The trench conductive layer includes a vertical portion that abuts and covers the sidewall 176 of the trench regions 154 and a horizontal portion that covers the bottom surface (or base) 178 of the trench regions 154. These vertical and horizontal portions are continuous and connected parts of the trench conductive layer that can be produced in a same fabrication step. The continuous trench conductive layer (the I/O interconnects 152) functions as I/O connection points (or regions) of the semiconductor device 150 and allows for electrical communication between internal circuitry of the semiconductor device 150 and an external system (or device), such as the PCB.

In some examples, the semiconductor device 150 include a multi-metal routing layer 158 (for simplicity referred to herein as a routing layer 158), which can be located on a first face of the semiconductor device 150, opposite of a second face of the semiconductor device 150 on which the I/O interconnects 152 are located. The routing layer 158 includes metal layers 160-164, with metal regions that can be separated from each other by a dielectric material 166, as illustrated in FIG. 1B. The dielectric material 166 used in the routing layer 158 can be the same or similar to the dielectric material 110 of FIG. 1A. The metal layers 160-164 can function as routing paths for electrical signals, power, and/or ground connections between one or more active regions of the substrate 156, one or more other metal layers, and/or one or more external systems and/or devices (e.g., the PCB). The dielectric material 166 provides electrical insulation between adjacent metal layers in the routing layer 158 to prevent electrical interference and shorting while providing mechanical stability. In the example of FIG. 1B, one or more metal regions of the first metal layer 160 can be in physical and electrical contact with a respective interconnect of the I/O interconnects 152, thus establishing a conductive pathway between a respective I/O interconnect of the I/O interconnects 152 and corresponding internal circuitry of the semiconductor device 150.

In some examples, the substrate 156 includes the trench regions 154 and trench regions 168, as illustrated in FIG. 1B. The trench regions 168 extend vertically through the substrate 156 and are filled with a dielectric material 170. The dielectric material 170 can be the same or similar to the dielectric material 118 of FIG. 1A. The dielectric material 170 provides electrical isolation and mechanical stability within the substrate 156. The dielectric material 170 extends to cover a top surface 172 of the substrate 156, as illustrated in FIG. 1B. Within the trench regions 168, the dielectric material 170 covers portions of the surface 174 of the routing layer 158. Thus, the dielectric material 170 extends from the top surface 172 of the substrate 156, through a body of the trench regions 168 (or the substrate 156), to the surface 174 of the routing layer 158. This arrangement isolates the I/O interconnects 152 from active regions of the semiconductor device 150 and, in some instances, prevents electrical interference or shorting between the I/O interconnects 152.

As illustrated in FIG. 1B, the trench regions 154 can be partially filled with (or contain) a metal material that forms the I/O interconnects 102 corresponding to the trench conductive layer. The trench regions 154 with the partially filled metal material correspond to the I/O interconnects 152 of the semiconductor package 150. The (continuous) trench conductive layer in the trench regions 154 can be formed from a conductive metal material, such as Copper or Aluminum. In some examples, the I/O interconnects 152, formed by depositing a conductive metal material into the trench regions 154, include a vertical portion that abuts and covers the sidewall 176 of the trenched regions 154 and a horizontal portion that covers the bottom surface (or base) 178. The horizontal portion of the trench conductive layer (the I/O interconnects 152) covers at least a portion of a surface of a respective metal region of the first metal layer 160 and is in physical and electrical contact with this metal region, thereby providing (or forming) an electrical path to the internal circuitry of the semiconductor device 150. Additionally, the horizontal portion of the trench conductive layer can also cover different portions of the surface 174 of the routing layer 158 than the dielectric material 170, as illustrated in FIG. 1B.

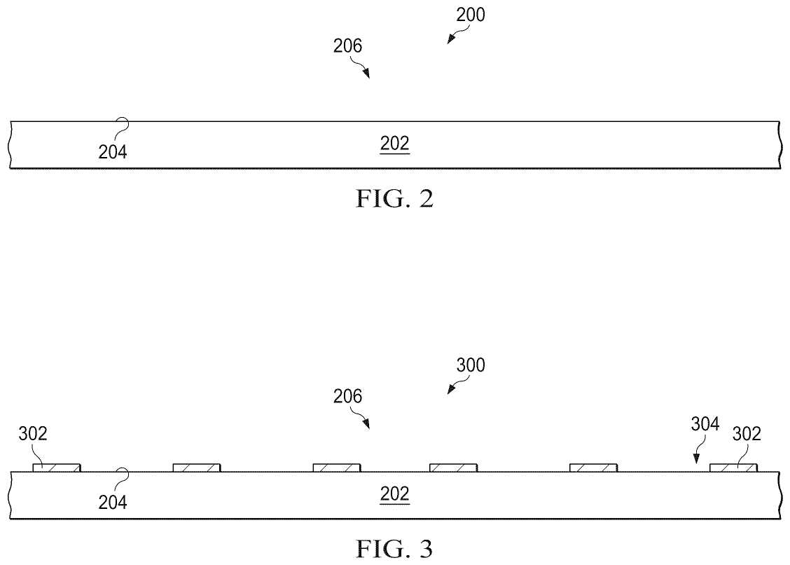

FIGS. 2-21 illustrate stages of a method for fabricating (e.g., assembling) a semiconductor package, such as described herein (e.g., the semiconductor device 100 of FIG. 1A or the semiconductor device 150 of FIG. 1B). In some examples, a wafer direct packaging process stages can include all or some of the stages of the method for fabricating the semiconductor package. Thus, in some examples, the stages of the method of FIGS. 2-21 can be used to implement the wafer direct packaging process. As illustrated in FIG. 2, at a first stage 200, a wafer 206 can be prepared. In yet some examples, at the first stage 200, the wafer 206 can be received or provided after front-end fabrication. Thus, in some examples, the method for fabricating the semiconductor package can be part of a wafer back-end fabrication process. The wafer 206 includes a substrate 202, which can be a wafer's based material and can function as a foundation for subsequent fabrication steps, as described herein. The substrate 202 can be a silicon substrate. In yet some examples, the substrate 202 is referred to as a wafer substrate. The substrate 202 includes an active silicon layer, which can be an upper portion of the substrate 202 and can contain active regions where electrical components can be formed. An active region refers to an area or portion within the active silicon layer representative of circuitry. The active regions in the active silicon substrate can be isolated and designed to form building blocks of an integrated circuit (IC). The active silicon layer can be formed during front-end fabrication, a stage in semiconductor manufacturing where active components, such as transistors, diodes, and/or capacitors etc., are fabricated within the silicon wafer. For example, the active regions can be formed on a top surface 204 of the substrate 202 and can be separated by isolation structures (e.g., by shallow trench isolation (STI) or field oxide (FOX)) to prevent electrical interference between adjacent active regions.

At a second stage 300, as illustrated in FIG. 3, a first metal layer 302 can be formed on the top surface 204 of the substrate 202. The first metal layer 302 can be used for routing power and/or signals (and in some instances providing a ground path) between the active regions and external components, such as a printed circuit board (PCB) to which the semiconductor package (after a fabrication process as described herein) can be mounted. Thus, the first metal layer 302 can function as an input/output (I/O) connection layer as this metal layer establishes an electrical path between the active regions in the active silicon layer and external interfaces, such as a PCB.

As illustrated in FIG. 3, the first metal layer 302 includes metal regions that are physically separate from one another and are located on the top surface 204 of the substrate 202. The metal regions of the first metal layer 302 can be referred to as first metal regions. Metal regions of the first metal layer 302 on the top surface 204 can be isolated by gaps 304. The gaps 304 are open spaces created during the patterning of the first metal layer 302 and are defined by an absence of metal material (used to form the first metal layer 302) on the top surface 204 of the substrate 202. Each metal region of the first metal layer 302 can be electrically coupled (e.g., through one or more vias) to one or more circuit components within the corresponding active region in the active silicon layer and/or other metal layers, such as described herein. In some examples, at the second stage 300, the first metal layer 302 can be formed on the top surface 204 of the substrate 202 through a process that can include depositing a thin metal film (e.g., aluminum or copper) over the substrate 202. This metal film can be patterned using photolithography and etching processes to define the first metal regions of the first metal layer 302.

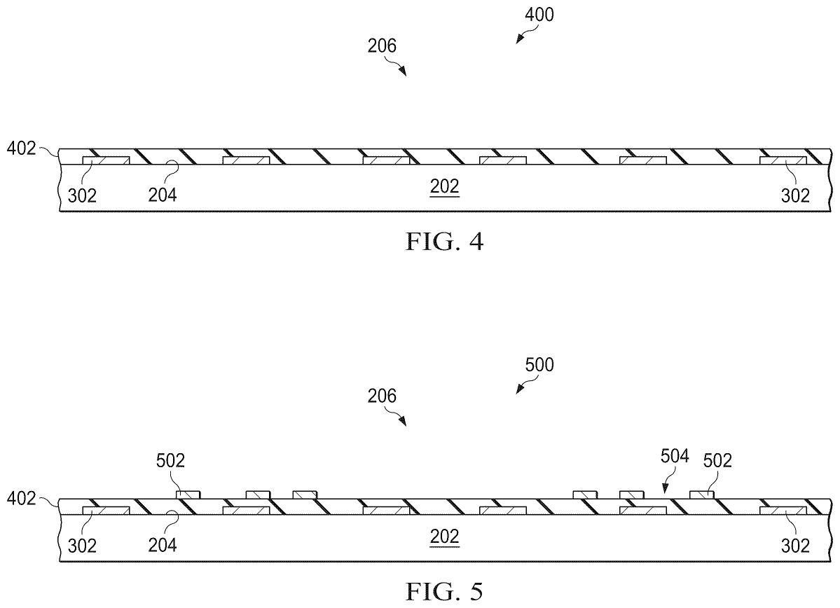

At a third stage 400, as illustrated in FIG. 4, a dielectric material 402 (e.g., silicon dioxide (SiO₂), silicon nitride (Si₃N₄), or a low-k dielectric material), can be deposited over the top surface 204 of the substrate 202 to form interlayer dielectric (ILD). The dielectric material 402 can be the same or similar to the dielectric material 110 of FIG. 1A. The dielectric material 402 is deposited over the first metal layer 302 and fills the gaps 304 to insulate neighboring first metal regions of the first metal layer 302 from each other to prevent electrical shorting while providing mechanical stability for subsequent fabrication steps. Once deposited, the dielectric material 402 encapsulates the first metal regions and fills the gaps 304. The dielectric material 402 can be deposited using chemical vapor deposition (CVD) or physical vapor deposition (PVD).

At a fourth stage 500, as illustrated in FIG. 5, a second metal layer 502 is formed on the dielectric material 402. In some examples, the second metal layer 502 can be electrically coupled to the first metal layer 302 through vertical interconnects (e.g., vias) that can be formed within the dielectric material 402. In yet some examples, the second metal layer 502 can provide additional routing paths for one or more signals, ground and/or power planes. The second metal layer 502 can support connections between different metal regions of the first metal layer 302, other metal layers and/or the active regions of the substrate 202. The second metal layer 502 can be formed on the dielectric material 402 by depositing a metal film, in some instances, using a method similar to that used for the first metal layer 302. One or more metal regions of the second metal layer 502 can be isolated by gaps 504 to prevent electrical interference or shorting between corresponding metal regions. The gaps 504 are open spaces created during the patterning of the second metal layer 502 and are defined by an absence of metal material (used to form the second metal layer 502) on a top surface of the dielectric material 402.

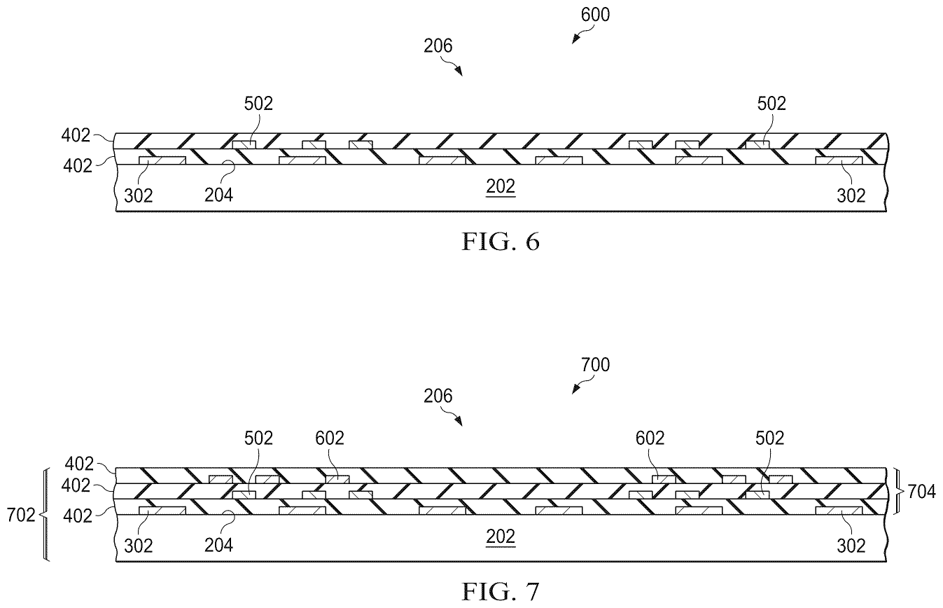

At a fifth stage 600, the dielectric material 402 can be deposited over the second metal layer 502 to form another ILD layer and fill the gaps 504 between the second metal regions of the second metal layer 502 to isolate corresponding metal portions and prevent electrical interference or shorting, as illustrated in FIG. 6. The dielectric material 402 deposited at the fifth stage 600 can provide mechanical stability and insulation between neighboring metal regions of the second metal layer 502. The dielectric material 402 can be deposited according to one or more examples herein using deposition techniques, such as those described herein. Once deposited, the dielectric material 604 encapsulates the second metal regions and fills the gaps 504, creating a planarized surface for subsequent layers.

In some examples, at a sixth stage 700, a metal layer fabrication process can be repeated, which can result in an intermediate wafer structure 702, as illustrated in FIG. 7. The metal layer fabrication process can include depositing an additional metal layer and insulating the deposited metal layer with the dielectric material 402 (e.g., forming additional ILD layers) in the same or similar manner as described herein at the second and third stages 300-400. Thus, each repetition of the metal layer fabrication process adds an additional metal layer for signals, power and/or ground routing and corresponding dielectric insulation to maintain signal integrity and mechanical stability. A number of additional metal layers that are used during fabrication can be based on a design consideration or requirement for the semiconductor package.

For example, at the sixth stage 700, the structure can include a third metal layer 602, which can be electrically coupled to the first and/or second metal layers 302, 502 and/or active circuitry (active regions) on the substrate 202. As illustrated in FIG. 7, the first, second, and third metal layers 302, 502, 602 along with the dielectric material 402 can collectively be referred to or form a multi-metal routing layer 704. In some examples, at the stage 700, the wafer 206, which includes the substrate 202 (having the active silicon layer), the first, second and third metal layers 302, 502, 602, and the dielectric material (layers) 402 can be referred to as a “wafer after fabrication” indicating completion of back-end fabrication steps for forming the multi-metal routing layer 704.

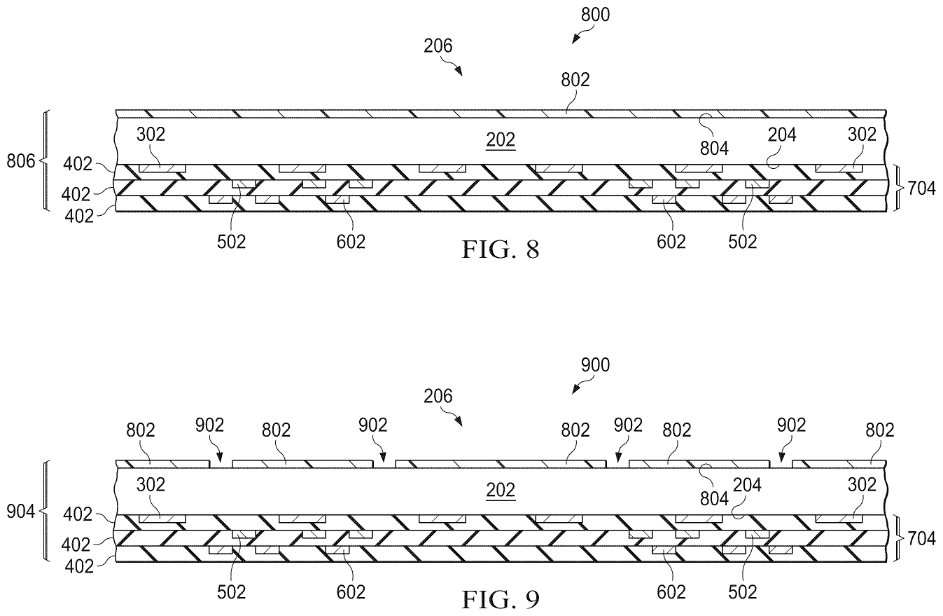

In some examples, at a seventh stage 800, a photoresist material 802 can be deposited on a bottom surface 804 of the substrate 202, which is opposite a side on which the multi-metal routing layer 704 has been formed, resulting in an intermediate wafer structure 806, as illustrated in FIG. 8. The photoresist material 802 functions as a photo-definable masking material for a subsequent etching process.

In some examples, at an eighth stage 900, the photoresist material 802 can be patterned (e.g., using photolithography) to define (form) a first etch pattern on an exposed surface (the bottom surface 804) of the substrate 202, resulting in an intermediate wafer structure 904, as illustrated in FIG. 9. The first etch pattern can be formed by selectively removing portions of the photoresist material 802 to expose regions (or surface portions) 902 on the bottom surface 804 of the substrate. The exposed portions (the exposed regions 902) correspond to areas where a first set of deep trenches can be formed during a first trenching process and thus are not protected by a mask or resist (the photoresist material 802). The remaining portions of the photoresist material 802 that have not been removed function as a protective mask during the first trenching process. The first trenching process can include in some examples anisotropic etching techniques, such as reactive ion etching (RIE), to achieve a desired trench shape and/or depth.

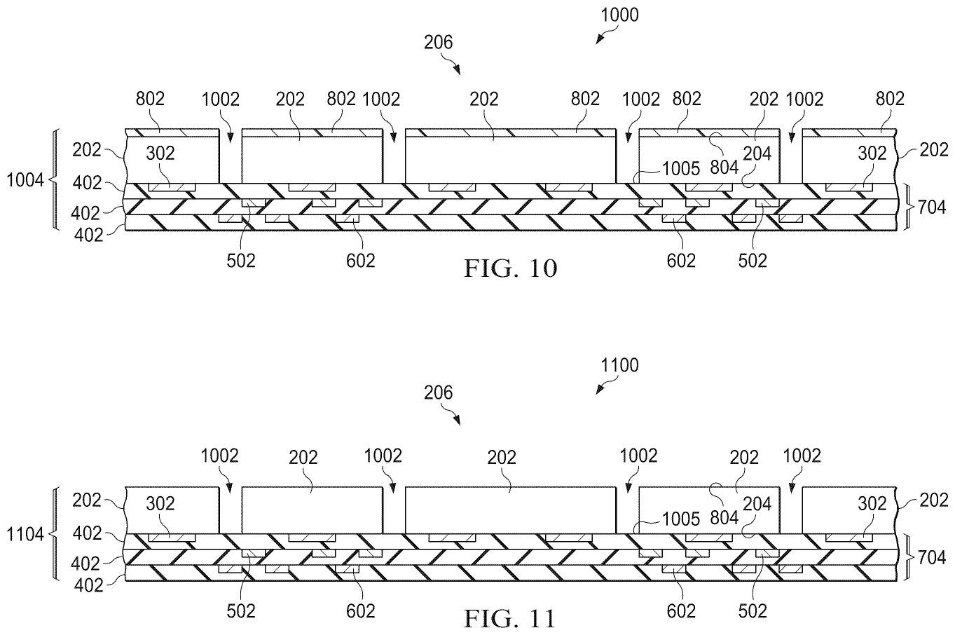

In some examples, at a ninth stage 1000, the first trenching process can be performed to remove portions of the substrate 202 beneath the exposed regions 902, forming trenched regions 1002 in the substrate 202, as illustrated in FIG. 10, resulting in an intermediate wafer structure 1004, as illustrated in FIG. 10. The trenched regions 1002 (the first set of trench regions) are empty voids in the substrate 202 created by removing silicon material from the substrate 202. These voids extend vertically through a body of the substrate 202 to expose a portion of a surface 1005 of the dielectric material 402 between neighboring or adjacent first metal regions of the first metal layer 302. In some examples, the trenched regions 1002 can be referred to as deep trench regions. The portion of the surface 1005 of the dielectric material 402 that becomes exposed during the first trenching process can be based on a dimension and alignment of the first etch pattern used to define the exposed regions 902. The first etch pattern can specify a size, shape, and location of areas on the substrate 202 where the material is removed, thereby exposing corresponding surfaces of the dielectric material 402.

In some examples, at a tenth stage 1100, the remaining portions of the photoresist material 802 can be removed, resulting in an intermediate wafer structure 1104, as illustrated in FIG. 11. In some examples, the remaining portions of the photoresist material 802 can be removed by using a chemical stripping process, such as by applying a photoresist stripper solution or performing a different process.

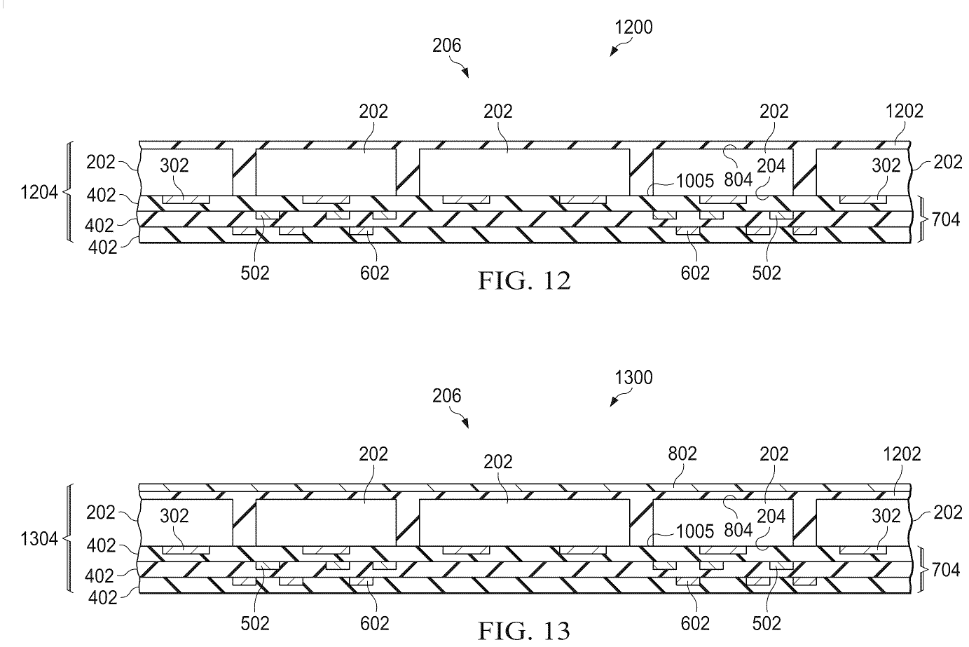

In some examples, at an eleventh stage 1200, a dielectric material 1202 can be deposited over the bottom surface 804 of the substrate 202, covering the bottom surface 804 and filling the trenched regions 1002, resulting in an intermediate wafer structure 1204, as illustrated in FIG. 12. The dielectric material 1202 can be the same or similar to the dielectric material 118 of FIG. 1A. The dielectric material 1202 can be deposited using spin coating or other same or similar depositing techniques. In some examples, the dielectric material 1202 can have a composition that is the same or similar to the dielectric material 402. In other examples, the dielectric material 1202 can have a different composition than the dielectric material 402.

In some examples, at a twelfth stage 1300, a photoresist material 802 can be deposited over the dielectric material 1202, resulting in an intermediate wafer structure 1304, as illustrated in FIG. 13. The photoresist material 802 can be deposited in the same or similar manner as described herein. The photoresist material 802 deposited at the twelfth stage 1300 can function as a photo-definable masking material for subsequent etching processes to define additional features, such as described herein.

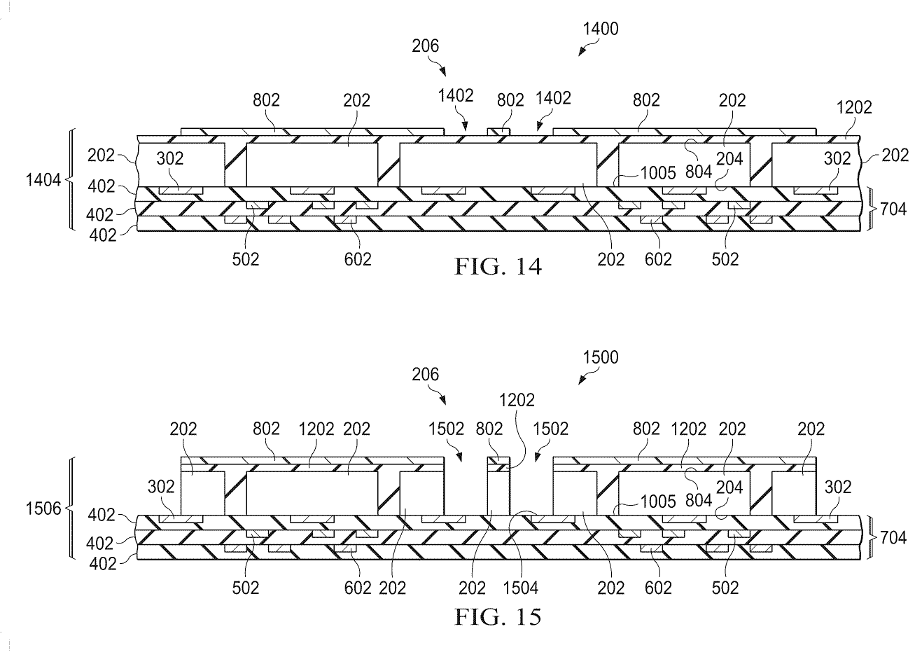

In some examples, at a thirteenth stage 1400, the photoresist material 802 deposited on the dielectric material 1202 can be patterned (e.g., using photolithography) to define (form) a second etch pattern on a surface of the dielectric material 1202, resulting in an intermediate wafer structure 1404, as illustrated in FIG. 14. The second etch pattern can be formed by selectively removing portions of the photoresist material 802 deposited on the surface of the dielectric material 1202 to expose regions (or surface portions) 1402 of the dielectric material 1202. The exposed portions (the exposed regions 1402) of the dielectric material 1202 correspond to areas where a second set of deep trenches can be formed during a second trenching process and thus are not protected by a mask or resist (the photoresist material 802). The remaining portions of the photoresist material 802 deposited on the dielectric material 1202 that have not been removed function as a protective mask during the second trenching process.

In some examples, at a fourteenth stage 1500, the second trenching process can be performed to remove portions of the dielectric material 1202 and additional portions of the substrate 202 beneath the exposed regions 1402, forming trenched regions 1502 in the substrate 202, as illustrated in FIG. 15. Thus, at the fourteenth stage 1500, an intermediate wafer structure 1506, as illustrated in FIG. 15, can be provided. The first set of trench regions and the second set of trench regions can be referred to as deep trenches in the substrate 202 as these trenches are formed through the body of the substrate 202. The trenched regions 1502 (the second set of trench regions) are empty voids created by removing additional portions of the substrate 202, as illustrated in FIG. 15. These voids extend vertically through the body of the substrate 202, to a surface defined by a surface 1504 of a respective first metal region of the first metal layer 302 and the surface 1504 of the dielectric material 402. Thus, the second trenching process exposes another portion of the surface 1005 of the dielectric material 402 in combination with a portion of the surface 1504 of the respective first metal region of the first metal layer 302. The second trenching process forms the trenched regions 1502 at particular locations in the intermediate wafer structure 1404 so that, after the trenched regions 1502 are filled with a conductive material (e.g., metal) and the wafer 206 is diced into individual dies, as described herein, the filled trenches can be located at a perimeter of each die. These filled trenches function as I/O interconnects (e.g., the I/O interconnects 102 of FIG. 1A) for a completed semiconductor package, allowing for electrical communication between the semiconductor package and an external system or device (e.g., the PCB).

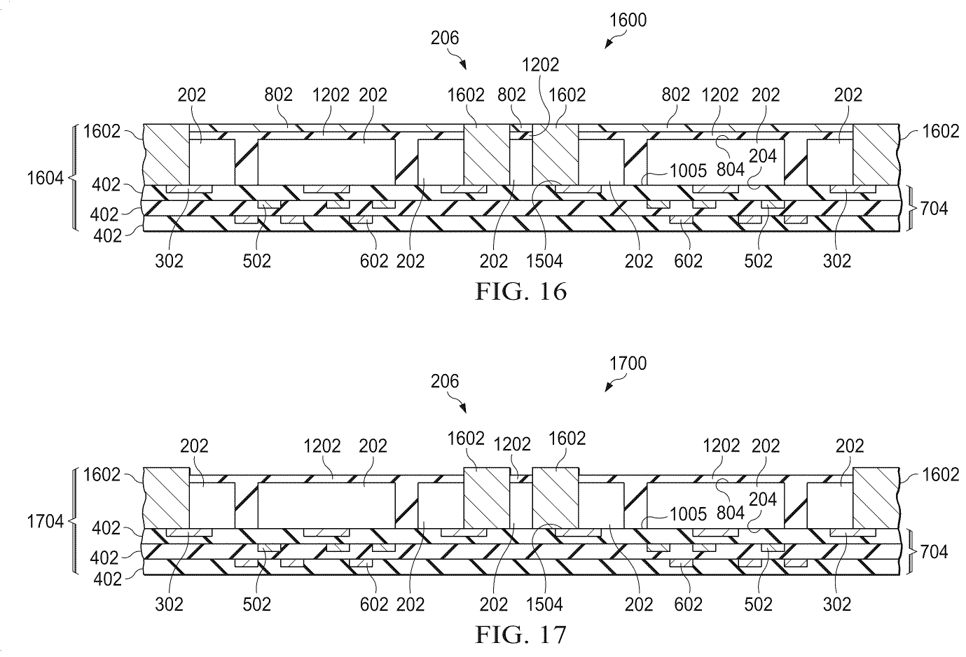

In some examples, the method proceeds from the fourteenth stage 1500 to a fifteenth stage 1600, as illustrated in FIG. 16, which can be referred to herein as a first example. In yet other examples, the method proceeds from the fourteenth stage 1500 to a fifteenth stage 1900, as illustrated in FIG. 19, which can be referred to herein as a second example. In the first example, at the fifteenth stage 1600, the trenched regions 1502 can be filled with a metal material to fill the trenched regions 1502 to provide metal filled trenched regions 1602, resulting in an intermediate wafer structure 1604, as illustrated in FIG. 16. Filling the trenched regions 1502 with a conductive material can be referred to as plugging. The metal filled trenched regions 1602 correspond to I/O interconnects, such as described herein. Thus, the trench regions 1602 with the filled metal material can be the I/O interconnects of the semiconductor device. The conductive metal material used for plugging the trenched regions 1502 can include metals such as copper, aluminum, and/or tungsten. A plugging process can involve techniques such as electroplating, CVD, or PVD to deposit the metal material into the trenched regions 1502. Excess metal material on the wafer 206 can be removed using chemical-mechanical planarization (CMP) to achieve a planarized surface. Accordingly, the I/O interconnects (the metal filled trenched regions 1602) can be formed within the substrate 202 using a deep trench etching process, as described herein.

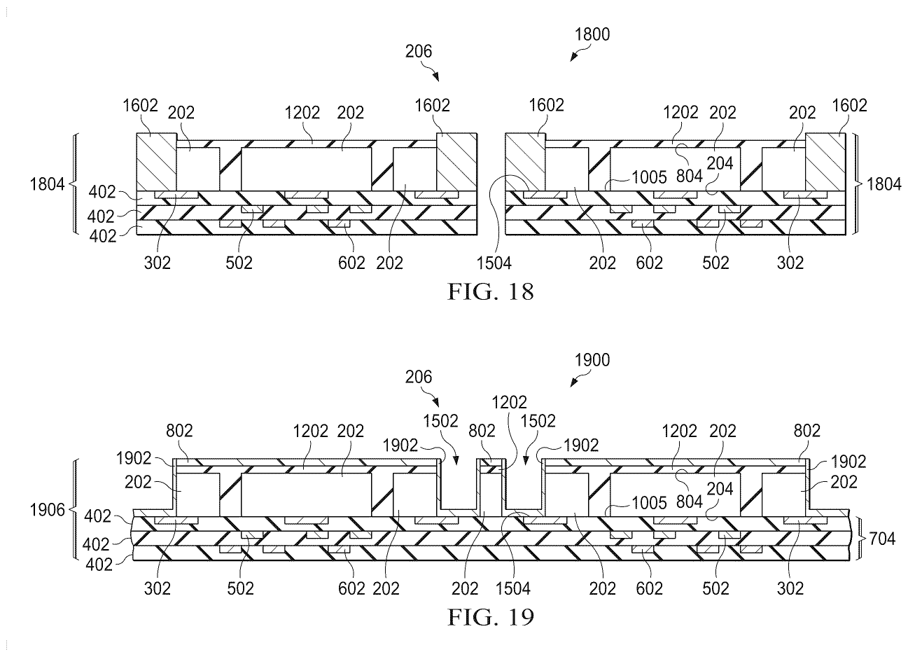

In some instances, in the first example, at the sixteenth stage 1700, the remaining portions of the photoresist material 802 deposited on the dielectric material 1202 can be removed, resulting in an intermediate wafer structure 1704, as illustrated in FIG. 17. The method can proceed from the sixteenth stage 1700 to the seventeenth stage 1800 in the first example. At the seventeenth stage 1800, a singulation process can be performed. Singulation can include partitioning the wafer 206, resulting in individual semiconductor packages/devices 1804, as illustrated in FIG. 18. A respective semiconductor package 1804 can correspond to the semiconductor device 100 of FIG. 1A. By way of example, singulation can include laser dicing, mechanical sawing, or plasma dicing. Singulation can be used to cut along predefined scribe lines or dicing streets, which are areas on the wafer 206 that are intentionally left free of circuit components so that cutting the wafer 206 does not damage one or more functional regions (active regions) of the semiconductor packages 1804. For the semiconductor device 100 of FIG. 1A, singulation includes use of a mechanical saw because of a thickness of the metal material 178, which restricts the use of laser or plasma dicing methods. The mechanical saw process may need a larger die size to accommodate an about 80 μm saw street. In some examples, for the semiconductor device 150 of FIG. 1B, laser or plasma dicing could be employed, as thinner metal layers, such as the trench conductive layer, can be structured to support such methods. An optional step at this point could including plating exposed surface of metal filled trench regions 1602 with tin, tin/nickel or gold to prevent corrosion or oxidation on the exposed surfaces of metal filled trench regions 1602.

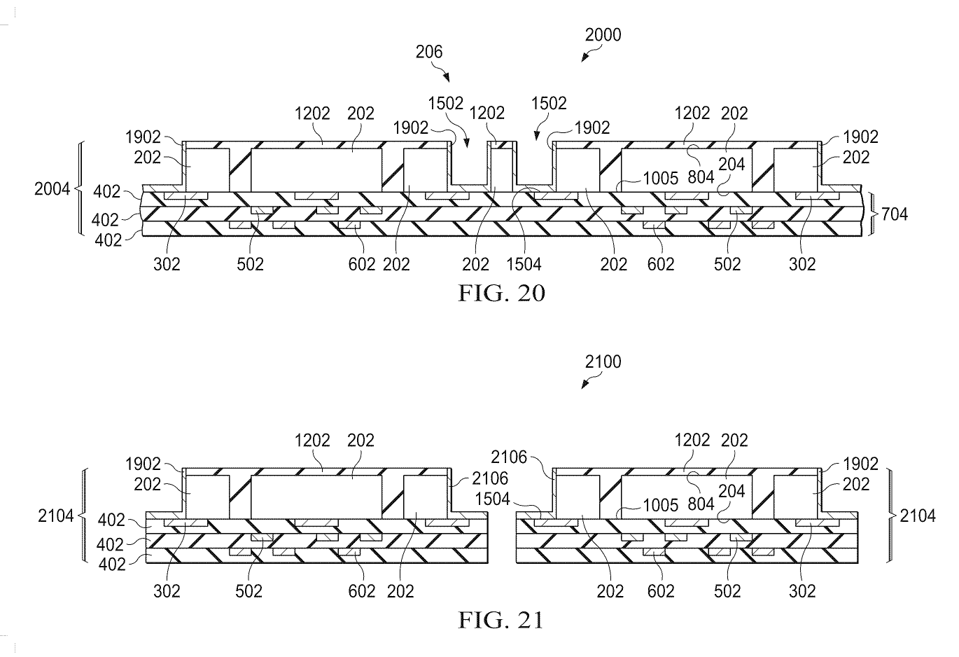

In yet other examples, such as the second example, the method proceeds from the fourteenth stage 1500 to the fifteenth stage 1900, as illustrated in FIG. 19. At the fifteenth stage 1900, in the second example, the trenched regions 1502 are metalized to deposit (form) a conductive material (or metal material) 1902 in the trenched regions 1502, resulting in an intermediate wafer structure 1906, as illustrated in FIG. 19. The deposited conductive material forms a continuous metal shell in the trenched regions 1502, referred to as a trench conductive layer, as illustrated in FIG. 19. The trench conductive layer includes a vertical portion that covers the sidewalls of the trenched regions 1502 and a horizontal portion that covers the base of the trenched regions 1502. These vertical and horizontal portions are continuous and connected, forming an uninterrupted conductive pathway. A metallization process can include depositing a conductive layer along inner surfaces of the trenched regions 1502, ensuring the conductive layer is about uniformly formed along the sidewalls and base of the trenched regions 1502. This process can utilize techniques such as CVD, atomic layer deposition (ALD), or PVD, which can be used to create a metal coating (or layer) on the surfaces of trenched regions 1502. Thus, the conductive material 1902 does not completely fill the trenched regions 1502 but forms a continuous conductive layer over the surfaces of the trenched regions 1502, as illustrated in FIG. 20. The conductive material 1902 can include materials, such as copper, tungsten, or aluminum. The thickness of the conductive material 1902 can be controlled during deposition to ensure that the conductive material 1902 meets electrical and mechanical specifications for a semiconductor package. For example, to ensure reliable I/O functionality, the conductive material 1902 can be designed with a controlled thickness during deposition to meet electrical resistance and current-carrying requirements while maintaining structural integrity. After forming the conductive material 1902, excess metal on the surface of the substrate 202 can be removed.

In some instances, in the second example, after forming the conductive material 1902, the trenched regions 1502 can be filled or plugged with a dielectric material, such as described herein. The dielectric material can be deposited into a hollow interior of the conductive material 1902. The dielectric material fills a void within the trenched regions 1502 (left after depositing metal material therein to cover the inner surfaces of the trenched regions 1502). Once the dielectric material is deposited in the trenched regions 1502, excess material on a wafer surface can be removed through a planarization process, to expose top edges of the conductive material 1902 to allow for electrical signals, power, and/or ground paths to pass between internal circuitry of the semiconductor package/device and external system or device, such as the PCB. In some examples, the dielectric material can be parylene, spin-on glass, or other materials that can be used for wafer coating.

In some instances, in the second example, at a sixteenth stage 2000, the remaining portions of the photoresist material 802 deposited on the dielectric material 1202 can be removed, resulting in an intermediate wafer structure 2004, as illustrated in FIG. 20. The method can proceed from the sixteenth stage 2000 to the seventeenth stage 2100 in the second example. At the seventeenth stage 2100, a singulation process can be performed, such as described herein to partition the wafer 206, resulting in the individual semiconductor package/devices 2104, as illustrated in FIG. 21. The wafer 206 can be partitioned in the same or similar manner, as described herein. A respective semiconductor package 2104 can correspond to the semiconductor device 150 of FIG. 1B in some instances. In some examples, during partitioning of the wafer 206, the trenched regions 1502 that are adjacent to other trenched regions 1502 in the wafer 206 become separated, forming individual conductive structures. Each conductive structure corresponds to a respective I/O interconnect 2106 of one of the semiconductor devices 2104 and includes a portion of the trench conductive layer of a respective trench region of the trenched regions 1502. For trenched regions 1502 that are not adjacent to other trenched regions 1502 after singulation, these trench regions with the conductive material (the trench conductive layer) is an I/O interconnect 2106 of one of the semiconductor packages 2104.

In some examples, to enhance a photo-sensitivity performance of the semiconductor packages 1804, 2104, the wafer 206 can be metalized or coated with an opaque material to block light penetration that could otherwise reach and affect active circuitry in the semiconductor packages 1804, 2104. This metalized or opaque layer can prevent stray light from interfering with a functionality of the active regions or degrading a performance of these active regions. In the first example, the surface of the wafer 206 can be metalized or coated after the sixteenth stage 1700 before the seventeenth stage 1800, and, in the second example, after the sixteenth stage 2000 before the seventeenth stage 2100.

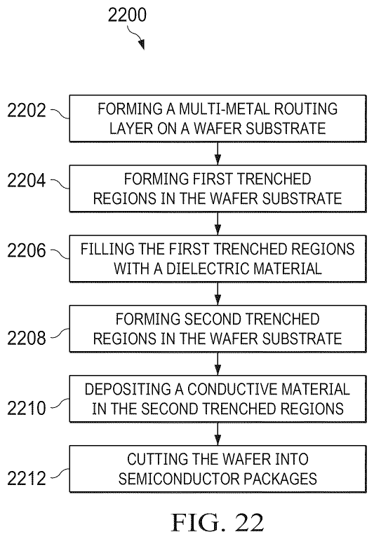

FIG. 22 is an example of a block diagram of a method 2200 for fabricating a semiconductor device, such as the semiconductor device 100 of FIG. 1A, the semiconductor device 150 of FIG. 1B, the semiconductor device package of FIG. 18, or the semiconductor package 2104 of FIG. 21. The method 2200 can begin at block 2202 with formation of a multi-metal routing layer (e.g., the multi-metal routing layer 122 of FIG. 1A, the multi-metal routing layer 158 of FIG. 1B or the multi-metal routing layer 704 of FIG. 7) on a first surface of a substrate of a wafer, which can be referred to herein as a wafer substrate. At block 2204, first trenched regions (e.g., the trenched regions 1002 of FIG. 10) can be formed in the wafer substrate. The first trenched regions can extend from the first surface of the wafer substrate to a second surface of the wafer substrate (e.g., the bottom surface 804 of the substrate 202) and expose a non-conductive portion of the multi-metal routing layer, such as the dielectric material 402. Thus, in some examples, the first trenched regions can be referred to as first deep trenches. At block 2206, the first trenched regions with 1002 can be filled with a dielectric material (e.g., the dielectric material 1202 of FIG. 12).

At block 2208, second trenched regions (the trenched regions 1502 of FIG. 15) can be formed in the wafer substrate. The second trenched regions can extend from the first surface of the wafer substrate to the second surface of the wafer substrate and expose a conductive portion of the multi-metal routing layer, such as a metal region of the first metal layer 302, as illustrated in FIG. 15. The second set of trenched regions provide electrical access to the multi-metal routing layer and thus to active circuitry that can be on the wafer substrate. Thus, in some examples, the second trenched regions can be referred to as second deep trenches. At block 2210, a conductive material (metal material) is deposited within the second trenched regions. In some examples, at block 2210, the conductive material is deposited to fill the second trenched regions, resulting in metal-filled trenched regions 1602, as illustrated in FIG. 16, which correspond to I/O interconnects (e.g., the I/O interconnects 102 of FIG. 1A) for the semiconductor package. In other examples, at block 2210, the conductive material is deposited along inner surfaces of the second trenched regions, which can be used as I/O interconnects. At block 2212, the wafer substrate is cut (or sliced) into individual components corresponding to individual semiconductor devices, such as described herein.

In some examples, the semiconductor device, fabricated according to examples herein, can be mounted on a PCB. For example, in some instances, the PCB can include pads corresponding to landing areas or terminals where the semiconductor package can be electrically and mechanically connected via the I/O interconnects. In a non-limiting example, the pads can be 60 micrometers (μm) Copper (Cu) pads. To establish these connections, solder can be micro-dispensed onto PCB pads with a dispensing precision of less than about 50 μm (in a non-limiting example), enabling accurate alignment and reliable electrical and mechanical connections between the semiconductor package and the PCB. Alternatively, solder paste or ball drop can be applied to the wafer substrate before singulation, providing another method for establishing robust connections during assembly.

Accordingly, a semiconductor package fabricated using the wafer direct packaging process, as described herein, can be formed during the wafer processing stage, eliminating a need for traditional assembly-based packaging steps, such as die attachment, wire bonding, flip-chip bumping, lead frame attachment, or encapsulation with mold compounds. Unlike conventional packaging methods that rely on surface-level bond pads and assembly materials (e.g., mold compounds, solder balls, and die attach adhesives), the wafer direct packaging process integrates I/O interconnects into the wafer substrate. This integration can be achieved through trenching and metallization techniques as described herein, which form metalized trenches that can function as high-density, reliable electrical pathways for power, ground, and/or signal routing. By embedding I/O interconnects within the wafer substrate, the wafer direct packaging process eliminates size and pitch constraints typically imposed by solder balls in WLP techniques. This allows for greater miniaturization and design flexibility in semiconductor devices. Moreover, the resulting bond pad-less design reduces material usage, simplifies manufacturing, and avoids reliability concerns associated with traditional assembly-based methods, such as delamination, thermal expansion mismatches, and mechanical stress failures. The wafer direct packaging process enables an entire chip, as diced from the wafer, to function as a final packaged product that is ready for direct integration into a system, such as onto a PCB. Without requiring additional packaging layers or encapsulation, this process achieves superior thermal and mechanical performance, making the process preferred for high-performance and miniaturized applications. Furthermore, this process can be adapted for use with flip-chip on lead (FCOL) configurations, further extending this process's versatility and applicability across a variety of semiconductor designs.

In this description, unless otherwise stated, “about,” “approximately” or “substantially” preceding a parameter means being within +/−10 percent of that parameter. Modifications are possible in the described embodiments and other embodiments are possible within the scope of the claims.

What is claimed is:

1. A semiconductor package comprising:
a substrate, the substrate including first and second trench regions that extend through a body of the substrate, and
wherein the first trench regions include a dielectric material and the second trench regions include a metal material, the second trenched regions with the metal material corresponding to input-output (I/O) interconnects of the semiconductor package.

2. The semiconductor package of claim 1, wherein the metal material partially fills the second trenched regions and the second trench regions with the partially filled metal material correspond to the I/O interconnects of the semiconductor package.

3. The semiconductor package of claim 2, wherein the metal material forms a trench conductive layer along inner surfaces of the second trench regions, the trench conductive layer defining a conductive pathway for the I/O interconnects of the semiconductor package.

4. The semiconductor package of claim 1, wherein the metal material fills the second trenched regions and the second trench regions with the filled metal material correspond to the I/O interconnects of the semiconductor package.

5. The semiconductor package of claim 4, wherein the I/O interconnects include a body portion that extends through the body of the substrate and a protruding portion that extends above a surface of the substrate.

6. The semiconductor package of claim 1, further comprising a multi-metal layer comprising one or more metal layers, wherein one or more of the I/O interconnects are electrically coupled to one of the one or more metal layers.

7. The semiconductor package of claim 6, wherein the multi-metal layer comprises a dielectric material that is different from the dielectric material in the first trench regions.

8. The semiconductor package of claim 7, wherein the dielectric material in the first trench regions is a spin-on glass (SOG) or parylene.

9. A semiconductor package comprising:
a substrate, the substrate including first trench regions and second trench regions, the first and second trench regions extending through a body of the substrate, and
wherein the first trench regions are filled with a dielectric material and the second trench regions are partially filled with a metal material, the second trench regions with the partially filled metal material corresponding to input-output (I/O) interconnects of the semiconductor package.

10. The semiconductor package 9, wherein the metal material forms a trench conductive layer along inner surfaces of the second trench regions, the trench conductive layer defining a conductive pathway for the I/O interconnects of the semiconductor package.

11. The semiconductor package of claim 10, wherein the trench conductive layer includes a vertical portion that runs along vertical sidewalls of the second trench regions and a horizontal portion that runs along bases of the second trench regions, the inner surfaces including the vertical sidewalls and the bases of the second trench regions.

12. The semiconductor package of claim 9, further comprising a multi-metal layer comprising one or more metal layers, wherein one or more of the I/O interconnects are electrically coupled to one of the one or more metal layers.

13. The semiconductor package of claim 12, wherein the multi-metal layer comprises a dielectric material that is different from the dielectric material in the first trench regions.

14. The semiconductor package of claim 13, wherein the dielectric material in the first trench regions is a spin-on glass (SOG) or parylene.

15. The semiconductor package of claim 9, wherein the dielectric material that fills the second trench regions further covers a top surface of the substrate.

16. A method for fabricating a semiconductor package, the method comprising:
forming first trenched regions in a wafer substrate;
filling the first trenched regions with a dielectric material;
forming second trench regions in the wafer substrate;
depositing a conductive material within the second trenched regions; and
partitioning the wafer substrate into one or more semiconductor packages, wherein the second trench regions with the deposited conductive material correspond to input-output (I/O) interconnects of the one or more semiconductor packages.

17. The method of claim 16, wherein the depositing comprises filling the second trench regions with the conductive material to provide metal-filled trench regions, the metal-filled trench regions corresponding to the I/O interconnects.

18. The method of claim 16, wherein the depositing comprises partially filling the second trench regions with the conductive material to provide partially filled second trench regions, each partially filled second trench region including a trench conductive layer.

19. The method of claim 18, wherein the partitioning comprises splitting one or more of the partially filled second trench regions into one or more conductive structures corresponding to a respective one of the I/O interconnects, wherein each conductive structure includes a portion of the trench conductive layer.

20. The method of claim 16, further comprising forming a multi-metal layer comprising one or more metal layers on the wafer substrate, wherein one or more of the I/O interconnects are electrically coupled to one of the one or more metal layers.
